(19) United States
(12) Patent Application Publication
(10) Pub. No.: US 2025/0081521 A1
(43) Pub. Date: Mar. 6, 2025

(54) ELECTRONIC DEVICE

(71) Applicant: InnoLux Corporation, Miao-Li County (TW)

(72) Inventors: Chen-Yu LIN, Miao-Li County (TW); Ming-Chih TSAI, Miao-Li County (TW)

(73) Assignee: InnoLux Corporation, Miao-Li County (TW)

(21) Appl. No.: 18/784,878

(22) Filed: Jul. 25, 2024

(30) Foreign Application Priority Data
Aug. 29, 2023 (CN) 202311091273.7

(51) Int. Cl. H01L 29/786; H01L 27/12

(52) U.S. Cl. CPC H10D 30/6723; H10D 86/443; H10D 86/60

(57) ABSTRACT

An electronic device including a substrate, a light-shielding layer, a first insulating layer, a semiconductor layer, a second insulating layer and a drain is disclosed. The light-shielding layer is disposed on the substrate. The first insulating layer is disposed on the light-shielding layer. The semiconductor layer is disposed on the first insulating layer. The second insulating layer is disposed on the semiconductor layer and has a hole, and the hole exposes a portion of the first insulating layer. The drain is connected to the semiconductor layer through the hole. A first minimum distance exists between the above portion of the first insulating layer and the light-shielding layer, a second minimum distance exists between the semiconductor layer and the light-shielding layer, and a ratio of the first minimum distance to the second minimum distance is greater than or equal to 0.1 and less than or equal to 1.0.

### BACKGROUND OF THE DISCLOSURE

### 1. Field of the Disclosure

The present disclosure relates to an electronic device, and more particularly to an electronic device including a light-shielding layer and an insulating layer.

### 2. Description of the Prior Art

With the progress of technology, electronic devices have become indispensable items in modern life. The elements in the electronic device can be electrically connected with each other through contact holes, and the distances between elements in products that having pixels with a small size may reduce correspondingly. At positions adjacent to the contact holes, other layers may be exposed due to processes such as etching, patterning, etc., resulting in short circuit of layers formed subsequently.

### SUMMARY OF THE DISCLOSURE

One of objectives of the present disclosure is to provide an electronic device, so as to reduce the probability of short circuit, thereby improving the reliability of the electronic device.

An embodiment of the present disclosure provides an electronic device. The electronic device includes a substrate, a light-shielding layer, a first insulating layer, a semiconductor layer, a second insulating layer and a drain. The light-shielding layer is disposed on the substrate. The first insulating layer is disposed on the light-shielding layer. The semiconductor layer is disposed on the first insulating layer. The second insulating layer is disposed on the semiconductor layer and has a hole, and the hole exposes a portion of the first insulating layer. The drain is connected to the semiconductor layer through the hole. A first minimum distance exists between the above portion of the first insulating layer and the light-shielding layer, a second minimum distance exists between the semiconductor layer and the light-shielding layer, and a ratio of the first minimum distance to the second minimum distance is greater than or equal to 0.1 and less than or equal to 1.0.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a partial top-view schematic diagram of an electronic device according to a first embodiment of the present disclosure.

FIG. 2 is a partial cross-sectional schematic diagram of an electronic device according to a first embodiment of the present disclosure.

FIG. 3 is a partially enlarged schematic diagram of the electronic device shown in FIG. 2.

FIG. 4 is a partial cross-sectional schematic diagram of an electronic device according to a second embodiment of the present disclosure.

FIG. 5 is a partial cross-sectional schematic diagram of an electronic device according to a third embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device or structure, and certain components in various drawings may not be drawn to scale. In addition, the number and dimension of each component shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include”, “comprise” and “have” are used in an open-ended fashion, and thus should be interpreted to mean “include, but not limited to . . . ”. When the terms “include”, “comprise” and/or “have” are used in the description of the present disclosure, the corresponding features, areas, steps, operations and/or components would be pointed to existence, but not limited to the existence or addition of one or a plurality of the corresponding or other features, areas, steps, operations, components and/or combinations thereof.

When an element or layer is referred to as being “on” or “connected to” another element or layer, it may be directly on or directly connected to the other element or layer, or intervening elements or layers may be presented (indirect condition). In contrast, when an element is referred to as being “directly on” or “directly connected to” another element or layer, there are no intervening elements or layers presented.

The directional terms mentioned in this document, such as “up”, “down”, “front”, “back”, “left”, “right”, etc., are only directions referring to the drawings. Therefore, the directional terms used are for illustration, not for limitation of the present disclosure.

The ordinal numbers used in the description and claims, such as “first”, “second”, “third”, etc., are used to describe elements, but they do not mean and represent that the element(s) have any previous ordinal numbers, nor do they represent the order of one element and another element, or the order of manufacturing methods. The ordinal numbers are used only to clearly discriminate an element with a certain name from another element with the same name. The claims and the description may not use the same terms. Accordingly, in the following description, a first constituent element may be a second constituent element in a claim.

According to the embodiments of the present disclosure, the thickness, length and/or width of each element and/or the distance between elements may be measured by an optical microscope (OM), a scanning electron microscope (SEM) or other suitable means. For example, the thickness, length and/or width of each element and/or the distance between elements may be measured from an image of the cross-sectional structure obtained by the scanning electron microscope, but not limited herein.

The terms “equal”, “identical” or “the same”, and “substantially” or “approximately” generally mean being within 20% of a given value or range, or being within 10%, 5%, 3%, 2%, 1% or 0.5% of a given value or range.

The electronic device of the present disclosure may be applied to a display device, a light-emitting device, a backlight device, a virtual reality device, an augmented reality device, an antenna device, a sensing device or a tiled device, but not limited herein. The electronic device may include a bendable or flexible electronic device. The electronic device may include, for example, liquid crystals, light emitting diodes, fluorescence, phosphors, other suitable display media or combinations of the above, but not limited herein. The display device may include a non-self-emissive display device or a self-emissive display device. The antenna device may include a liquid-crystal type antenna device or an antenna device other than liquid-crystal type, and the sensing device may include a sensing device used for sensing capacitance, light, heat or ultrasonic waves, but not limited herein. The electronic device may include electronic elements such as passive elements and active elements, for example, capacitors, resistors, inductors, diodes, transistors, etc. The diode may include a light-emitting diode or a photodiode. For example, the light-emitting diode may include an organic light-emitting diode (OLED), a mini light-emitting diode (mini LED), a micro light-emitting diode (micro LED) or a quantum dot light-emitting diode (quantum dot LED), but not limited herein. The tiled device may be, for example, a display tiled device or an antenna tiled device, but not limited herein. It should be noted that the electronic device may be any arrangement and combination of the above, but not limited herein. In addition, the appearance of the electronic device may be a rectangle, a circle, a polygon, a shape with curved edges or other suitable shapes. The electronic device may have a peripheral system such as a driving system, a control system, a light source system, etc., to support a display device, an antenna device, a wearable device (including an augmented reality device or a virtual reality device, for example), a vehicle-mounted device (including an automobile windshield, for example) or a tiled device.

It should be noted that the technical features in different embodiments described in the following can be replaced, recombined, or mixed with one another to constitute another embodiment without departing from the spirit of the present disclosure.

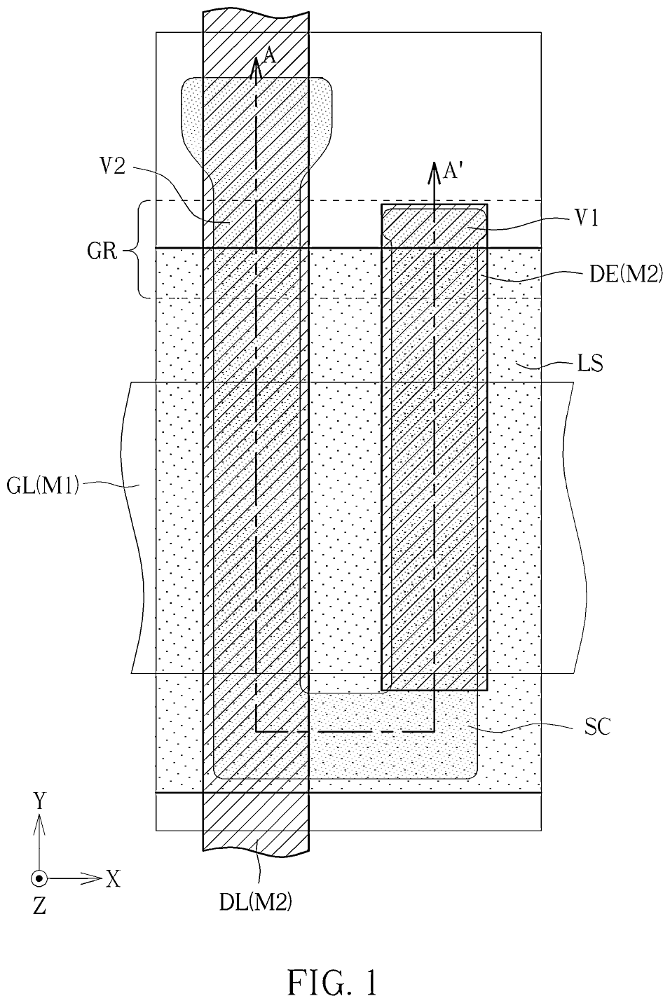

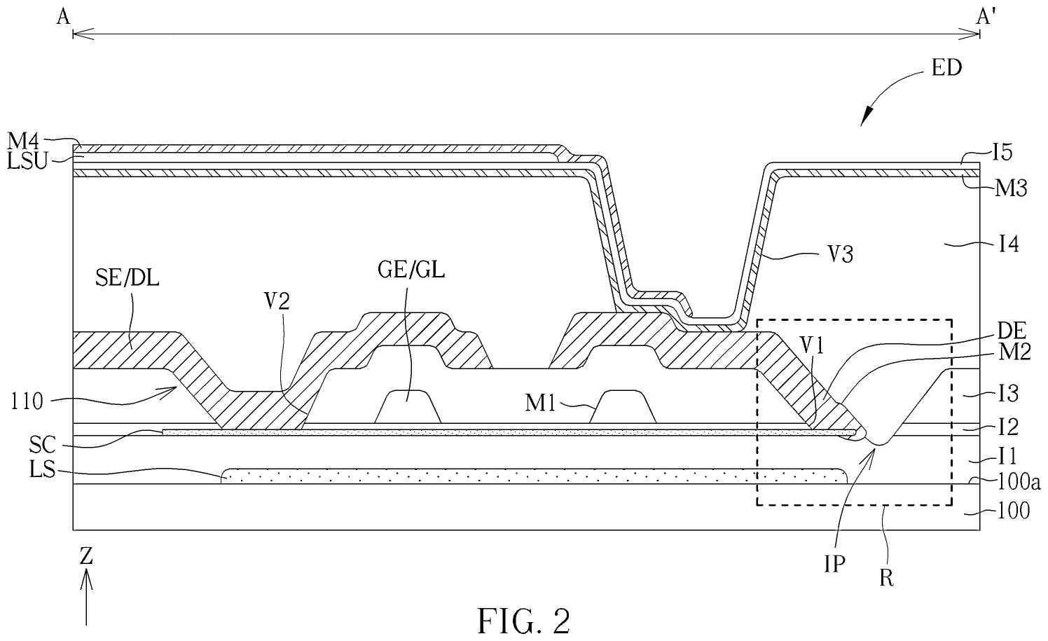

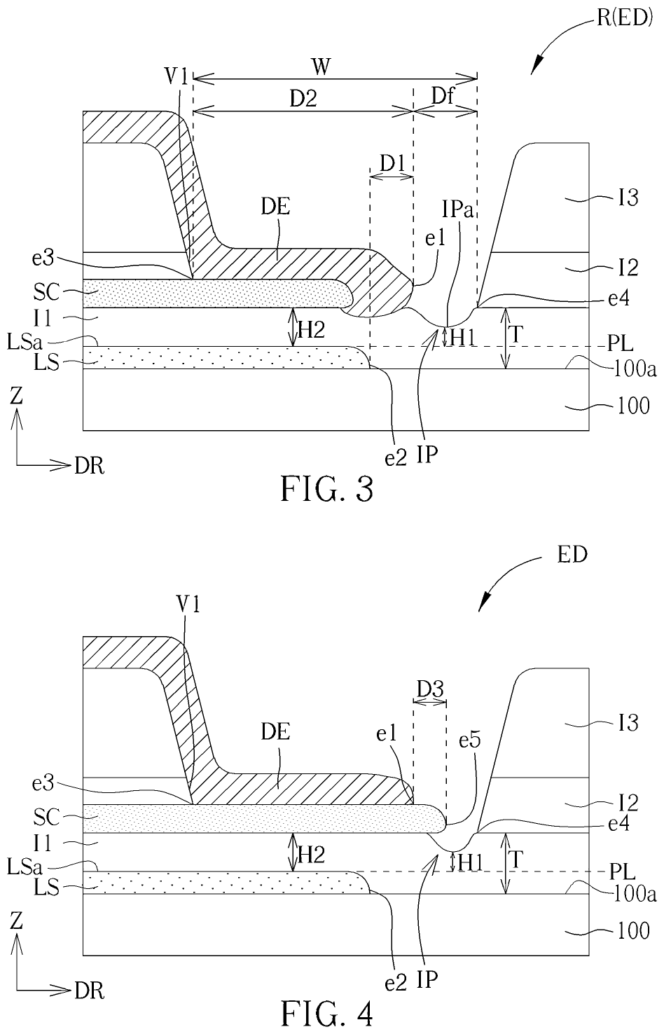

Please refer to FIG. 1, FIG. 2 and FIG. 3. FIG. 1 is a partial top-view schematic diagram of an electronic device according to a first embodiment of the present disclosure. FIG. 2 is a partial cross-sectional schematic diagram of an electronic device according to a first embodiment of the present disclosure. FIG. 3 is a partially enlarged schematic diagram of the electronic device shown in FIG. 2. For the conciseness of the drawings, FIG. 1 shows the top view of only a portion of elements of an electronic device ED shown in FIG. 2, and FIG. 3 shows the enlarged schematic diagram of only a portion of elements of the electronic device ED shown in FIG. 2. The partial cross-sectional structure of the electronic device ED corresponding to the section line A-A′ in FIG. 1 may be referred to FIG. 2, and the partially enlarged structure of the electronic device ED corresponding to the region R in FIG. 2 may be referred to FIG. 3. As shown in FIG. 1, FIG. 2 and FIG. 3, an electronic device ED includes a substrate 100, a light-shielding layer LS, a first insulating layer I1, a semiconductor layer SC, a second insulating layer I2 and a drain DE. The light-shielding layer LS is disposed on the substrate 100. The substrate 100 may include hard material or flexible material. The material of the substrate 100 includes, for example, glass, quartz, sapphire, ceramics, polyimide (PI), polycarbonate (PC), polyethylene terephthalate (PET), other suitable materials or combinations of the above materials, but not limited herein. The light-shielding layer LS may include, for example, metal material, black photoresist material or other materials with better light absorption, but not limited herein. In some embodiments, an insulating layer (not shown) may further be disposed between the substrate 100 and the light-shielding layer LS, but the present disclosure is not limited herein.

The first insulating layer I1 is disposed on the light-shielding layer LS, and the semiconductor layer SC is disposed on the first insulating layer I1. The second insulating layer I2 is disposed on the semiconductor layer SC and forms a portion of a hole V1, wherein the hole V1 exposes a portion IP of the first insulating layer I1. That is to say, the portion IP of the first insulating layer I1 is not covered by the second insulating layer I2. The drain DE is connected to the semiconductor layer SC through the hole V1. A portion of a projection of the semiconductor layer SC on the substrate 100 may be located within a projection of the hole V1 on the substrate 100, and the drain DE may be electrically connected to the semiconductor layer SC through the hole V1. Specifically, the electronic device ED may include a thin film transistor 110 disposed on the first insulating layer I1. The thin film transistor 110 may include the drain DE, a source SE, a gate GE and the semiconductor layer SC, and the second insulating layer I2 may be disposed between the gate GE and the semiconductor layer SC, which may serve as a gate dielectric layer in the thin film transistor 110. The electronic device ED may include a scan line GL and a data line DL disposed on the substrate 100. The scan line GL may extend along a direction X, and the data line DL may extend along a direction Y, wherein the direction X is not parallel to the direction Y. For example, the direction X may be perpendicular to the direction Y, but not limited herein. The gate GE of the thin film transistor 110 may be a portion of the scan line GL, and the source SE of the thin film transistor 110 may be a portion of the data line DL. In some embodiments, a plurality of scan lines GL and a plurality of data lines DL may be formed on the substrate 100, which intersect with each other to define a plurality of regions of pixels (or sub-pixels), and the thin film transistor 110 may serve as a driving element or a switching element of a pixel, and the electronic device ED may have a function of displaying images, but not limited herein.

As shown in FIG. 1 and FIG. 2, the electronic device ED may, for example, include the light-shielding layer LS, the first insulating layer I1, the patterned semiconductor layer SC, the second insulating layer I2, a first conductive layer M1 that is patterned, a third insulating layer I3 and a second conductive layer M2 that is patterned, which are disposed on an upper surface 100a of the substrate 100 along a direction Z in sequence. The direction Z may be a normal direction of the electronic device ED and parallel to a top-view direction of the electronic device ED, wherein the direction Z may be perpendicular to the upper surface 100a of the substrate 100 or a lower surface thereof for example, and the direction X and the direction Y may be perpendicular to the direction Z and parallel to the upper surface 100a of the substrate 100 respectively. The patterned first conductive layer M1 may form the scan line GL and the gate GE. The patterned conductive layer M2 may form the data line DL, the source SE and the drain DE. The drain DE may be electrically connected to the semiconductor layer SC through the hole V1 in the second insulating layer I2 and the third insulating layer I3, and the source SE may be electrically connected to the semiconductor layer SC through a hole V2 in the second insulating layer I2 and the third insulating layer I3. In some embodiments, for example, the hole V1 and the hole V2 shown in FIG. 2 may be formed by forming a groove GR extending along the direction X as shown in FIG. 1 in the second insulating layer I2 and the third insulating layer I3, but the present disclosure is not limited to the above. For example, the hole V1 and the hole V2 may be formed by forming a plurality of holes separated from each other in the second insulating layer I2 and the third insulating layer I3 in other embodiments. In the cross-sectional views shown in FIG. 2 and FIG. 3, one side (e.g., the left side) of the hole V1 may extend from the third insulating layer I3, through the second insulating layer 12, and to an upper surface of the semiconductor layer SC, so as to expose a portion of the semiconductor layer SC, and another side (e.g., the right side) of the hole V1 may extend from the third insulating layer I3, through the second insulating layer I2, and to an upper surface of the first insulating layer I1, so as to expose the portion IP of the first insulating layer I1.

As shown in FIG. 1, the light-shielding layer LS may be at least partially overlapped with the scan line GL in the direction Z, and in the direction Y, a width of the light-shielding layer LS may be greater than a width of the scan line GL. According to the embodiment shown in FIG. 1 to FIG. 3, the light-shielding layer LS may be partially overlapped with the hole V1 in the direction Z. Specifically, the light-shielding layer LS that is disposed may have a large size (for example, the light-shielding layer LS may have a large area or have a large width in the direction Y), so that the projection of the hole V1 on the substrate 100 may be at least partially located within a projection of the light-shielding layer LS on the substrate 100. As shown in FIG. 3, a portion the projection of the hole V1 on the substrate 100 may be located within the projection of the light-shielding layer LS on the substrate 100. According to the structural design of the light-shielding layer LS described above, the light leakage may be reduced and the electrical performance may be improved, and/or the region where the thin film transistor 110 is arranged and/or the pixel aperture region may be distinguished more obviously, so as to improve the contrast of the display image.

As shown in FIG. 2 and FIG. 3, in the direction Z, a first minimum distance H1 exists between the portion IP of the first insulating layer I1 exposed by the hole V1 and the light-shielding layer LS, a second minimum distance H2 exists between the semiconductor layer SC and the light-shielding layer LS, and a ratio of the first minimum distance H1 to the second minimum distance H2 is greater than or equal to 0.1 and less than or equal to 1.0, that is, 0.1≤H1/H2≤1.0. Specifically, in the direction Z, the minimum distance between an upper surface IPa of the portion IP of the first insulating layer I1 and a plane PL where an upper surface LSa of the light-shielding layer LS is located may be defined as the first minimum distance H1, and the minimum distance between a lower surface of the semiconductor layer SC and the upper surface LSa of the light-shielding layer LS may be defined as the second minimum distance H2. The first insulating layer I1 has a thickness T in the direction Z, and the thickness T of the first insulating layer I1 may be greater than or equal to 500 angstroms (Å) and less than or equal to 3000 angstroms. For example, the first minimum distance H1 may be 2600 Å, and the second minimum distance H2 may be 1300 Å, but not limited herein. The process of forming the hole V1 and/or the drain DE (e.g., a patterning process such as the etching process) may cause the portion IP of the first insulating layer I1 exposed by the hole V1 to have a concave surface, which may bring the risk of exposing the light-shielding layer LS. Therefore, through the above designs for the range of the ratio of the first minimum distance H1 to the second minimum distance H2 and/or the range of the thickness T of the first insulating layer I1, the first insulating layer I1 is capable of protecting the light-shielding layer LS, so as to reduce the risk of exposing the light-shielding layer, thereby reducing the probability of short circuit. For example, the probability of short circuit caused by the contact between the drain and the light-shielding layer due to the exposure of the light-shielding layer may be reduced, thereby improving the reliability of the electronic device.

According to the embodiment shown in FIG. 2, the electronic device ED may further include, for example, a fourth insulating layer I4, a third conductive layer M3, a fifth insulating layer I5 and a fourth conductive layer M4. The fourth insulating layer I4 is disposed on the second conductive layer M2 and has a hole V3, and the hole V3 exposes a portion of the drain DE. The third conductive layer M3 is disposed on the fourth insulating layer I4 and electrically connected to the drain DE through the hole V3. The fifth insulating layer I5 is disposed on the third conductive layer M3, and the fourth conductive layer M4 is disposed on the fifth insulating layer 15. The fifth insulating layer I5 and the fourth conductive layer M4 may be partially disposed in the hole V3, and the fifth insulating layer I5 is located between the fourth conductive layer M4 and the third conductive layer M3, so that the fourth conductive layer M4 within the hole V3 and the third conductive layer M3 are insulated from each other. For example, the third conductive layer M3 may serve as a pixel electrode, and the fourth conductive layer M4 may serve as a common electrode. In some embodiments, as shown on FIG. 2, the electronic device ED may further include a light-shielding element LSU disposed between the fifth insulating layer I5 and the fourth conductive layer M4, and the light-shielding element LSU may be partially overlapped with the data line DL in the direction Z, so as to reduce light leakage and improve the optical and/or electrical performance. The light-shielding element LSU may include, for example, metal material, black photoresist material or other materials with better light absorption, but not limited herein.

The first conductive layer M1 and the second conductive layer M2 may include metal material, such as aluminum, molybdenum, copper, titanium, other suitable materials or combinations of the above materials, but not limited herein. The semiconductor layer SC may include, for example, amorphous silicon, poly-silicon, metal oxide or combinations of the above, but not limited herein. The metal oxide includes, for example, indium-gallium-zinc oxide (IGZO), but not limited herein. The third conductive layer M3 and the fourth conductive layer M4 may include transparent conductive material, such as (but not limited to) indium tin oxide (ITO). The first insulating layer I1, the second insulating layer I2, the third insulating layer I3, the fourth insulating layer I4 and the fifth insulating layer I5 may include organic material, inorganic material, dielectric material or other suitable insulating materials. The organic material may include, for example, polyimide (PI), photosensitive polyimide (PSPI), epoxy, Ajinomoto build-up film (ABF) material or other suitable materials, but not limited herein. The inorganic material may include, for example, silicon oxide (SiOx), silicon nitride (SiN), silicon oxynitride (SiOxNy), other suitable materials or combinations of the above materials, but not limited herein. For example, the third insulating layer I3 may include dielectric material and serve as an inter-layer dielectric, the fourth insulating layer I4 may include organic material and serve as a planarization layer, and the fifth insulating layer I5 may include inorganic material and serve as a passivation layer, but not limited to the above.

According to the embodiment shown in FIG. 3, in a direction DR, an edge e1 of the drain DE may protrude from the light-shielding layer LS by a first distance D1, and the first distance D1 may be greater than or equal to 0.2 micrometers (μm). Through making the edge e1 of the drain DE protrude from the light shielding layer LS by the first distance D1 with a certain length, the risk of exposing the light-shielding layer LS due to the manufacturing process may be reduced, thereby reducing the probability of short circuit between the drain DE and the light-shielding layer LS. The direction DR may be perpendicular to the direction Z and parallel to the upper surface 100a of the substrate 100. For example, the drain DE may extend along the direction DR and the edge e1 of the drain DE protrudes from an edge e2 of the light-shielding layer LS, and the shortest distance between the edge e1 of the drain DE and the edge e2 of the light-shielding layer LS may be defined as the first distance D1.

The hole V1 may have a lower edge e3 close to the gate GE (shown in FIG. 2) and a lower edge e4 far from the gate GE. For example, in a cross-sectional view, the edge e3 and the edge e4 of the hole V1 are located at opposite ends in the direction DR, the edge e3 may be located at the boundary between the second insulating layer I2 and the semiconductor layer SC, and the edge e4 may be located at the boundary between the second insulating layer I2 and the first insulating layer I1. In the direction DR, the edge e1 of the drain DE may protrude from the edge e3 of the hole V1 by a second distance D2, and the second distance D2 may be greater than or equal to 0.3 micrometers, so that the area of the drain DE contacting with the semiconductor layer SC is increased, thereby reducing the risk of wiring disconnection. For example, the drain DE may extend along the direction DR and the edge e1 of the drain DE protrudes from the edge e3 of the hole V1, and the shortest distance between the edge e1 of the drain DE and the edge e3 of the hole V1 may be defined as the second distance D2. In the direction DR, the hole V1 has a width W, for example, the width W may be obtained by measuring the shortest distance between the edge e3 of the hole V1 and the edge e4 of the hole V1 along the direction DR. A difference Df between the width W and the second distance D2 may be greater than or equal to 0 and less than or equal to half of the width W, that is, Df=(W−D2) and 0≤Df≤W/2. Through the above design making the edge e1 of the drain DE protrude from the edge e3 of the hole V1 by the second distance D2 with a certain length, the area of the drain DE contacting with the semiconductor layer SC may be increased, and the risk of exposing the light-shielding layer LS due to the manufacturing process may be reduced. In some embodiments, as shown in FIG. 3, the difference Df may be equal to the shortest distance between the edge e1 of the drain DE and the edge e4 of the hole V1 in the direction DR.

The electronic device of the present disclosure is not limited to the above embodiments. Some embodiments of the electronic devices of the present disclosure will be detailed in the following. In order to simplify the illustration, the same elements in the present disclosure would be labeled with the same symbols. The differences between different embodiments are described in detail below, and the same features would not be described redundantly.

Please refer to FIG. 4. FIG. 4 is a partial cross-sectional schematic diagram of an electronic device according to a second embodiment of the present disclosure. An electronic device ED shown in FIG. 4 is different from the first embodiment shown in FIG. 3 in that, in the direction DR, an edge e5 of the semiconductor layer SC may protrude from the edge e1 of the drain DE by a third distance D3, so that the area of the drain DE contacting with the semiconductor layer SC is increased, and the protruding semiconductor layer SC may reduce the risk of exposing the light-shielding layer LS due to the manufacturing process, thereby reducing the probability of short circuit between the drain DE and the light-shielding layer LS. For example, the semiconductor layer SC may extend along the direction DR and the edge e5 of the semiconductor layer SC protrudes from the edge e1 of the drain DE, and the shortest distance between the edge e5 of the semiconductor layer SC and the edge e1 of the drain DE may be defined as the third distance D3. In other embodiments, the semiconductor layer SC may extend along the direction DR, and the edge e5 of the semiconductor layer SC may protrude from the edge e4 of the hole V1 by a distance. That is to say, a projection of the hole V1 on the substrate 100 may be located within a projection of the semiconductor layer SC on the substrate 100, so the protruding semiconductor layer SC may further reduce the risk of exposing the light-shielding layer LS, but not limited herein.

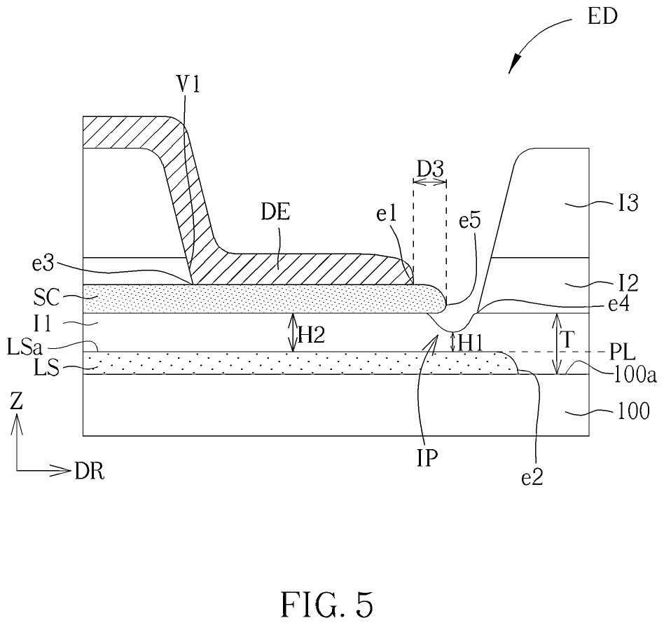

Please refer to FIG. 5. FIG. 5 is a partial cross-sectional schematic diagram of an electronic device according to a third embodiment of the present disclosure. An electronic device ED shown in FIG. 5 is different from the second embodiment shown in FIG. 4 in that, a projection of the hole V1 on the substrate 100 may be located within a projection of the light-shielding layer LS on the substrate 100. For example, the light-shielding layer LS may extend along the direction DR, and the edge e2 of the light-shielding layer LS may protrude from the edge e4 of the hole V1 by a distance. That is to say, the light-shielding layer LS may be overlapped with the hole V1 in the direction Z. The above light-shielding layer LS with a larger size may improve the contrast of the display image, but not limited herein.

From the above description, according to the electronic devices of the embodiments of the present disclosure, through the design for the range of the ratio of the first minimum distance between the portion of the first insulating layer and the light-shielding layer to the second minimum distance between the semiconductor layer and the light-shielding layer and/or the design for the thickness range of the first insulating layer, the risk of exposing the light-shielding layer may be reduced, so that the probability of short circuit may be reduced, thereby improving the reliability of the electronic device. Furthermore, through the structural design that the drain and/or the semiconductor layer protrude by a certain distance, the risk of exposing the light-shielding layer may be further reduced, and the area that the drain contacting the semiconductor layer may be increased.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate;
a light-shielding layer disposed on the substrate;
a first insulating layer disposed on the light-shielding layer;
a semiconductor layer disposed on the first insulating layer;
a second insulating layer disposed on the semiconductor layer and having a hole, wherein the hole exposes a portion of the first insulating layer; and
a drain connected to the semiconductor layer through the hole,
wherein a first minimum distance exists between the portion of the first insulating layer and the light-shielding layer, a second minimum distance exists between the semiconductor layer and the light-shielding layer, and a ratio of the first minimum distance to the second minimum distance is greater than or equal to 0.1 and less than or equal to 1.0.

2. The electronic device according to claim 1, wherein a thickness of the first insulating layer is greater than or equal to 500 angstroms and less than or equal to 3000 angstroms.

3. The electronic device according to claim 1, wherein in a direction, an edge of the drain protrudes from the light-shielding layer by a first distance.

4. The electronic device according to claim 3, wherein the first distance is greater than or equal to 0.2 micrometers.

5. The electronic device according to claim 1, wherein in a direction, an edge of the drain protrudes from an edge of the hole by a second distance.

6. The electronic device according to claim 5, wherein the second distance is greater than or equal to 0.3 micrometers.

7. The electronic device according to claim 5, wherein the hole has a width in the direction, and a difference between the width and the second distance is greater than or equal to 0 and less than or equal to half of the width.

8. The electronic device according to claim 1, wherein the light-shielding layer is partially overlapped with the hole.

9. The electronic device according to claim 1, wherein a projection of the hole on the substrate is located within a projection of the light-shielding layer on the substrate.

10. The electronic device according to claim 1, wherein in a direction, an edge of the semiconductor layer protrudes from an edge of the drain by a third distance.

11. The electronic device according to claim 1, further comprising a scan line disposed on the substrate, wherein a portion of the scan line forms a gate, and the second insulating layer is disposed between the gate and the semiconductor layer.

12. The electronic device according to claim 11, wherein the light-shielding layer is at least partially overlapped with the scan line.

13. The electronic device according to claim 12, wherein in a direction, a width of the light-shielding layer is greater than a width of the scan line.

14. The electronic device according to claim 11, further comprising a third insulating layer disposed on the second insulating layer and disposed between the gate and the drain.

15. The electronic device according to claim 14, further comprising:
a fourth insulating layer disposed on the drain and the third insulating layer, wherein the fourth insulating layer has another hole, and the another hole exposes a portion of the drain; and
a conductive layer disposed on the fourth insulating layer and electrically connected to the drain through the another hole.

16. The electronic device according to claim 15, further comprising a light-shielding element disposed on the conductive layer.

17. The electronic device according to claim 1, wherein the portion of the first insulating layer exposed by the hole has a concave surface.

18. The electronic device according to claim 1, wherein the hole has a first edge and a second edge that are located at opposite ends in a direction, the first edge is located at a boundary between the second insulating layer and the semiconductor layer, and the second edge of the edge is located at a boundary between the second insulating layer and the first insulating layer.

19. The electronic device according to claim 18, wherein a distance exists between an edge of the drain and the second edge of the hole in the direction.

20. The electronic device according to claim 19, wherein the hole has a width in the direction, and the distance is less than or equal to half of the width.
